(19) United States
(12) Patent Application Publication
(10) Pub. No.: US 2005/0067682 A1
(43) Pub. Date: Mar. 31, 2005

(54) Semiconductor device containing stacked semiconductor chips and manufacturing method thereof

(76) Inventors: Ryosuke Usui, Ichinomiya-city (JP); Hideki Mizuhara, Bisai-City (JP); Takeshi Nakamura, Sawa-gun (JP)

Correspondence Address: FISH & RICHARDSON P.C., CITIGROUP CENTER 52ND FLOOR, 153 EAST 53RD STREET, NEW YORK, NY, 10022-4611, US

(21) Appl. No.: 10/952,203

(22) Filed: Sep. 28, 2004

(30) Foreign Application Priority Data
Sep. 30, 2003 (JP) 2003-339127

(51) Int. Cl. H01L 21/44; H01L 29/40

(52) U.S. Cl. 257/686; 438/109; 257/692; 257/777

(57) ABSTRACT

Stacked interconnect layers each of which includes an interlayer dielectric film and an interconnect line made of copper, and solder resist layer formed as the top layer constitute a multilevel interconnect configuration. The first element, the second element and a circuit element are mounted on the surface of the configuration. The second element bonds to the first element by an adhesion layer. The upper surface of the first element is treated by plasma, and the second element is mounted on the surface.

### BACKGROUND OF THE INVENTION

1. Field of the Invention

This invention relates to a semiconductor device provided with semiconductor chips, and a manufacturing method thereof.

2. Description of the Related Art

Portable electronics devices such as a cellular phone, a PDA, a DVC and a DSC become increasingly sophisticated. The fabrication of the devices with a compact size and lightweight are indispensable so that such devices are accepted in the market. System LSI higher integrated is required for the realization of such devices. On the other hand, LSI used for the devices is required to be with a high functionality and a high performance for the realization of friendly and convenient electronics devices. For this reason, while the number of I/O is increasing with the acceleration of LSI chip integration, downsizing of the package is also required. The development of the packages appropriate to the board assembly of semiconductor components with a high density is strongly desired to satisfy both of the integration and the downsizing.

The method of stacking semiconductor chips, which is disclosed in Japanese Laid-Open Patent Application H11-204720, is known as a packaging technique to cater to the request of such integration. FIG. 1 shows a configuration of CSP (Chip Size Package) described in the related art. The semiconductor chip 1 with circuits formed thereon is mounted on the dielectric substrate 3 with the interconnect layer 4 formed thereon. The semiconductor chip 2 is mounted on the thermocompression sheet 7 formed on the semiconductor chip 1. The semiconductor chips 1 and 2 are connected with electrodes in the interconnect layer 4 by the wire 8. The semiconductor chips 1 and 2, and the wire 8 are sealed by resin.

When the semiconductor chips are stacked like this, however, the reliability of elements and the yield rate of the element manufacturing process sometimes decline because of the absence of adhesiveness between the semiconductor chips.

It becomes important to increase sufficiently the adhesion between stacked semiconductor elements when the semiconductor chips are stacked as described in the related art. The defective adhesion at the interface leads to the decline of element reliability because of the influence of heat stress or moisture.

Related Art List

JPA laid open H11-204720

### SUMMARY OF THE INVENTION

The present invention is achieved in view of the aforementioned circumstances and an object thereof is to provide a technique capable of improving adhesiveness between semiconductor chips in a package in which the semiconductor chips are stacked.

The semiconductor device according to one aspect of the present invention includes: a first semiconductor chip; and a second semiconductor chip mounted on the first semiconductor chip, wherein an upper surface of the first semiconductor chip is a plasma treatment surface, and the second semiconductor chip is mounted on the plasma treatment surface.

The manufacturing method of a semiconductor device according to one aspect of the present invention includes: forming a first semiconductor chip on a base material; performing plasma treatment of a surface of the base material and an upper surface of the first semiconductor chip; and forming a second semiconductor chip on the upper surface of the first semiconductor chip treated by plasma.

According to the present invention, the adhesiveness between the first semiconductor chip and the second semiconductor chip mounted thereon is significantly improved since the upper surface of the first semiconductor chip is a plasma treatment surface.

The upper surface of the semiconductor chip may be the surface of a chip itself or the surface of such film as resin formed on the chip. For example, the plasma treatment surface may be the upper surface of an overcoat film formed as the top layer of the chip or the upper surface of an adhesive film formed on the chip. The second semiconductor chip may be mounted on the plasma treatment surface directly, or on a film such as an adhesive film formed on the plasma treatment surface.

The plasma treatment is preferably performed by using a plasma gas including an inert gas and with no bias voltage applied. With this, the degradation of the semiconductor chip is prevented, and the surface with an excellent interface adhesiveness can be obtained. The bias voltage does not include a self bias voltage of the substrate.

The semiconductor device according to one aspect of the present invention may have a configuration including a base material provided with a conductor circuit, in which at least a part of the conductor circuit is exposed on the reverse side, and the first and the second semiconductor chips are formed on the obverse side of the base material. That is, the first and the second semiconductor chips may be formed on a base material with no supporting substrate. One of such configuration is ISB™ configuration which will be described below. When such the ISB™ configuration is adopted, the adhesiveness between the first and the second semiconductor chips with a higher-level is required although thin and lightweight packages can be realized.

This summary of the invention does not necessarily describe all necessary features so that the invention may also be a sub-combination of these described features.

### BRIEF DESCRIPTION OF THE DRAWINGS

FIG. 1 shows an example of a package configuration in which a plurality of semiconductor chips are stacked.

FIG. 2 shows a configuration of ISB™.

FIG. 3A shows manufacturing process of BGA.

FIG. 3B shows manufacturing process of ISB™.

FIG. 4 shows a configuration of a semiconductor device according to the first embodiment.

FIG. 5 shows a configuration of a semiconductor device according to the first embodiment.

FIG. 6 shows a manufacturing process of a semiconductor device according to the first embodiment.

FIG. 7 shows a manufacturing process of a semiconductor device according to the first embodiment.

FIG. 8 shows a manufacturing process of a semiconductor device according to the first embodiment.

FIG. 9 shows a manufacturing process of a semiconductor device according to the second embodiment.

FIG. 10 shows a manufacturing process of a semiconductor device according to the second embodiment.

FIG. 11 shows a configuration of a semiconductor device according to the third embodiment.

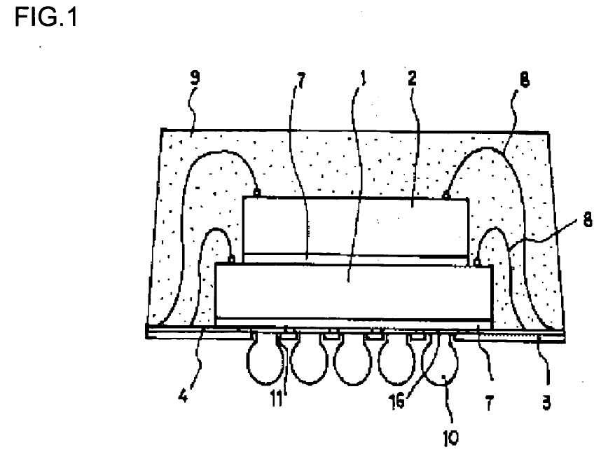

### DETAILED DESCRIPTION OF THE INVENTION

Although the invention will be described below based on the preferred embodiments, the ISB™ configuration introduced in each embodiment will be now described prior to it. ISB™ (Integrated System in Board) is a unique package developed by the inventors of the present invention. ISB™ is a unique coreless system-in package in the packaging techniques involving electric circuits including semiconductor bare chips mainly, and it has interconnect patterns made of copper but no core (base material) to support circuit components.

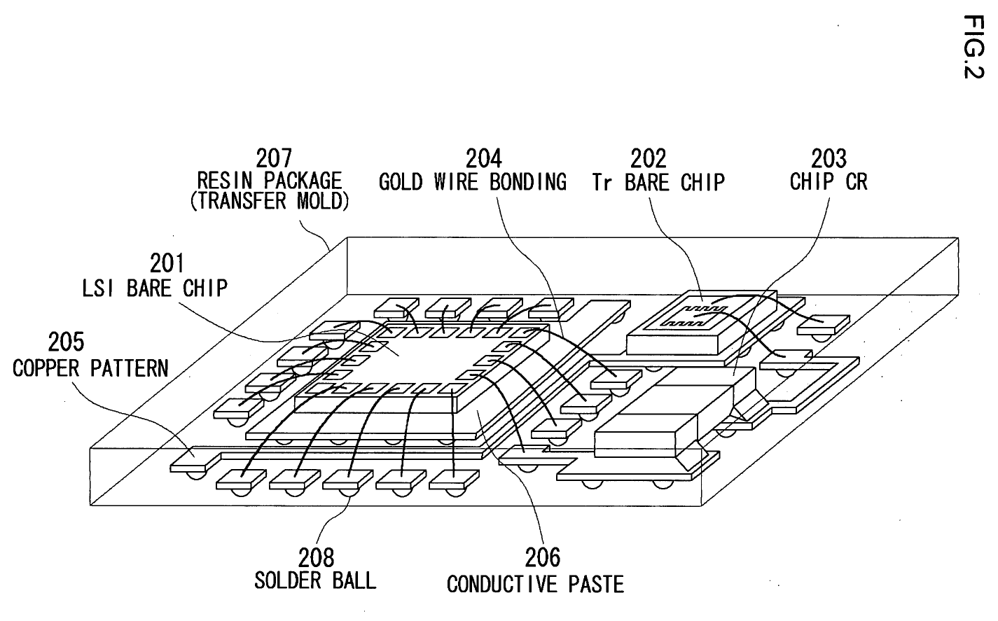

FIG. 2 shows a schematic illustration of an example of ISB™. Although a single interconnect layer is shown for a simple explanation of the overall configuration of ISB™, the configuration practically includes a plurality of interconnect layers stacked. This ISB™ has a configuration that includes the LSI bare chip 201, Tr bare chip 202 and the chip CR 203 connected by interconnect lines that include the copper pattern 205. The LSI bare chip 201 is connected with extraction electrodes and the interconnect lines by the gold wire bonding 204. The ISB™ is mounted on a printed circuit board by the conductive paste 206 formed beneath the LSI bare chip 201. ISB™ is entirely sealed with a resin package 207 made of epoxy resin and so on. Although the configuration that includes a single interconnect layer is shown in this figure, a multilayer interconnect configuration may be also adopted.

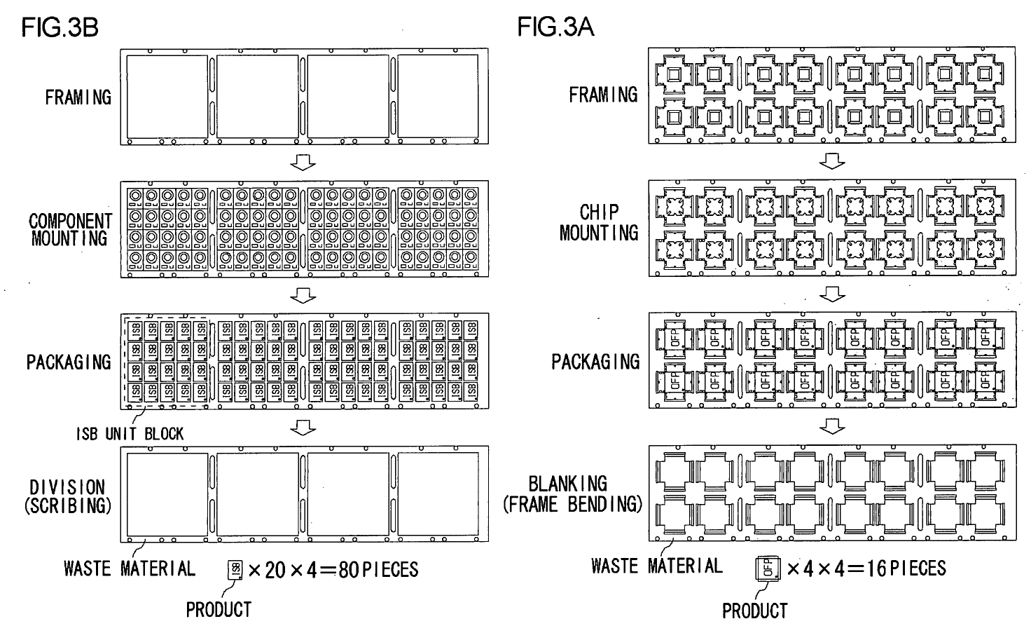

FIGS. 3A and 3B show a comparison of manufacturing processes of a conventional CSP and the ISB™ according to one aspect of the present invention. FIG. 3A shows a manufacturing process of the conventional CSP. A frame is firstly formed on a base substrate, and chips are mounted on the element formation areas segmented by the frame. After that, a package made of thermosetting resin is provided for each element, and blanking is performed for each element by using a metal die. In the final blanking process, the mold resin and the base substrate are cut simultaneously. Therefore, the roughness of the cut surface becomes a problem. Furthermore, since a large amount of waste material after the blanking process generates, a problem also arises from the viewpoint of environmental burden.

FIG. 3B shows the ISB™ manufacturing process. Frames are firstly formed on a metal foil. Circuit elements such as a LSI are mounted on interconnect patterns formed in each module formation area. After packaging each module, finished products are obtained by dicing along scribing areas. Since the metal foil as a base is removed after the packaging process and before the scribing process, only the resin layer is cut by dicing in the scribing process. Therefore, the roughness of the cut surface can be prevented, and the dicing can be performed more accurately.

The following advantages are obtained by the technique of ISB™.
(i) Transistors, ICs and LSIs can be made smaller and thinner because of the coreless assembly.
(ii) High-performance SIP (System-in Package) can be realized since a circuit including transistors, system LSIs, chip capacitors and chip resistors can be formed and packaged.
(iii) It becomes possible to develop a system LSI in a short term since existing semiconductor chips can be used in combination.
(iv) High rate of heat radiation can be obtained since the semiconductor bare chip is directly mounted on copper.
(v) Since the interconnect material is copper and there is no core material, the circuit interconnect has a low dielectric constant so that the excellent properties in high-speed transfer of data and in a high-frequency circuit can be obtained.
(vi) The formation of particle contamination of the electrode material can be suppressed because of the configuration where the electrodes are embedded in the package.
(vii) Environmental burden can be reduced since the package size is free, and the amount of the waste material per one package is one-tenth of that of SQEP package having 64 pins.
(viii) The concept of a system construction can be changed from a printed circuit board to mount components into a functional circuit board.
(ix) The design of ISP patterns is as easy as the design of printed circuit board patterns, and can be performed by engineers themselves in set manufacturers.

The semiconductor devices such as ISB™ have no supporting substrate. Therefore, from the viewpoint of improvement of the yield rate in the bonding process of semiconductor chips, it becomes an important technical problem to bond the first and the second semiconductor chips with a strong adhesion. Furthermore, ISB™ T has a configuration in which a bare chip that is not sealed by resin is directly mounted on a interconnect configuration, and therefore, the bare chip is easily influenced by moisture. It again becomes important to improve the adhesiveness between the chips from the viewpoint of avoidance of the moisture influence.

Next, the preferred embodiments of the present invention will be explained referring to figures.

First Embodiment

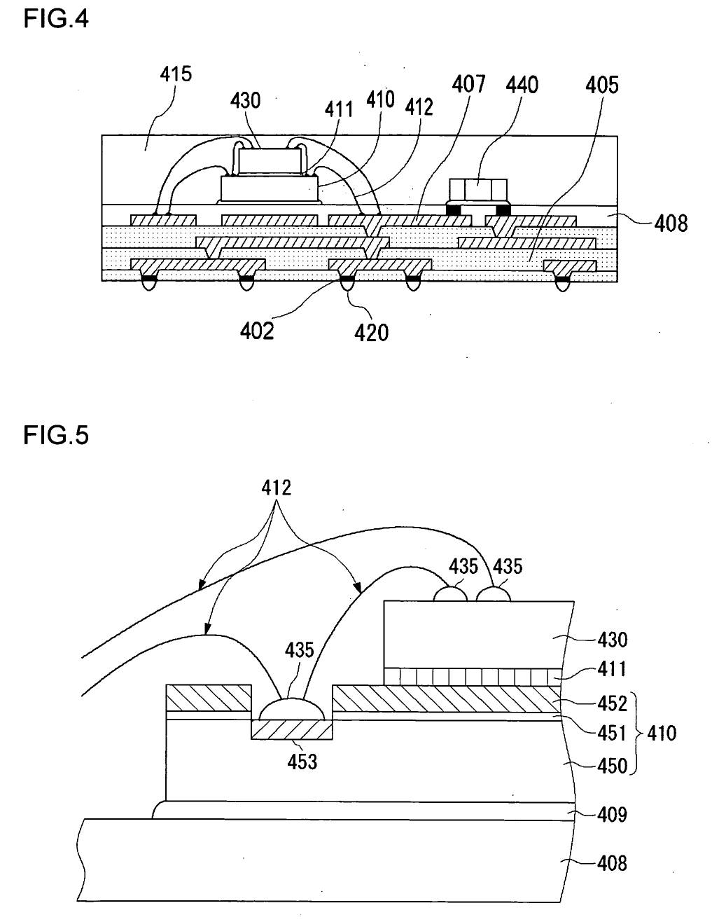

A semiconductor device having an ISB™ configuration described above will be taken as an example for a following explanation of the preferred embodiment of the present invention. FIG. 4 shows a cross sectional view of a semiconductor device according to the present embodiment. This semiconductor device includes a multilevel interconnect configuration, and the first element 410, the second element 430 and the circuit element 440 that are formed on the interconnect configuration. The multilevel interconnect configuration includes a plurality of interconnect layers stacked, each of which consists of the interlayer dielectric film 405 and the interconnect line 407 made of copper, and the solder resist layer 408 formed as the top layer. The solder ball 420 is provided on the backside surface of the multilevel interconnect configuration. The first element 410, the second element 430 and the circuit element 440 are molded by the mold resin 415.

The first element 410 is bonded with the second element 430 by the adhesion layer 411. The upper surface of the first element 410 is a plasma treatment surface, and the second element 430 is mounted on the surface. The details of the interface between the first element 410 and the second element 430 are shown in FIG. 5.

FIG. 5 shows a cross sectional view of the configuration in which the adhesion part 409, the first element 410 and the second element 430 are stacked on the solder resist layer. The first element 410 has a configuration in which the SiCN film 451 and the polyimide film 452 are stacked on the base material 450. The adhesion layer 411 under the second element 430 is stuck on the polyimide film 452. The SiCN film 451 and the polyimide film 452O have openings with exposing pad electrodes. The second element 430 is electrically connected with the first element 410 by the wire 412 fixed by the solder 435. The second element 430 and the first element 410 are electrically connected also with ISB™ T board by the wire 412, respectively (no figure).

It is preferable that the plasma treatment surface is cleaned adequately, and that the surface property is changed into that having a strong affinity for the adhesion layer 411, to obtain the significant effect of the surface modification of the polyimide film 452 by the plasma treatment.

The resin materials such as a melamine derivative such as BT resin, a liquid crystal polymer, an epoxy resin, a PPE resin, a polyimide resin, a fluorocarbon resin, a phenol resin and a thermosetting resin such as a polyamide bismaleimide can be selected for the solder resist layer 408, the interlayer dielectric film 405 and the mold resin 415 in FIG. 4, respectively. In particular, the liquid crystal polymer, the epoxy resin and the melamine derivative such as BT resin are preferably used since they have an excellent high-frequency property. Filler or additive may be arbitrarily added to the resin.

The adhesion layer 411 may be formed by coating die attach paste or by using a die attach film.

An epoxy resin, a BT resin and a liquid crystal polymer are preferably used for the dielectric base material. A semiconductor device with excellent high-frequency property and high product reliability can be obtained by using such a resin.

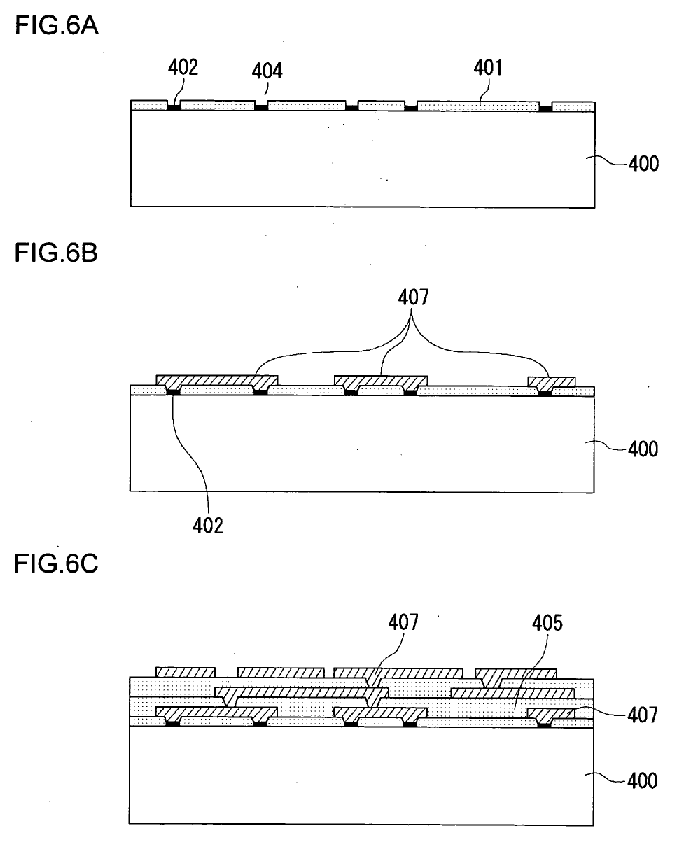

Next, a manufacturing method of the semiconductor device shown in FIG. 4 will be described in reference to FIGS. 6A to 8B. The via hole 404 is formed at a predetermined location on the metal foil 400, and the conductive film 402 is formed in the via hole 404 selectively as shown in FIG. 6A. More specifically, after coating the metal foil 400 by the photo resist 401, the conductive film 402 is formed on an exposed part of surface of the metal foil 400 by an electric field plating method. The conductive film 402 has a thickness of about 1 to 10 μm, for example. Since the conductive film 402 will become finally a backside electrode of a semiconductor device, gold or silver, which has a good adhesiveness for brazing filler metal such as solder, is preferably used for the conductive film 402.

After that, the interconnect pattern of the first layer are formed on the metal foil 400 as shown in FIG. 6B. First, chemical polishing is performed against the metal foil 400 for cleaning the surface and to form a rough surface. Next, the conductive film 402 on the metal foil 400 is entirely coated by thermosetting resin, and heat hardening is performed so that the film surface becomes flat. Next, a via hole with a diameter of about 100 μm reaching to the conductive film 402 is formed in the film. The via hole is formed by a laser processing in the present embodiment. Machining, chemical etching, and dry etching by using plasma can be also used to form the via hole. After that, etching residue is removed by laser exposure, and a copper plating layer is formed on overall the surface with embedding the via hole 404. The copper plating layer is etched by using a photo resist mask so that the interconnect line 407 made of copper is formed. The interconnect pattern can be formed by removing unnecessary copper foil by spraying etching solution to the surface exposed out of the resist, for example.

The formation of the interlayer dielectric film 405, the via hole and the copper plating layer, and the patterning of the copper plating layer mentioned above are repeated in turn so that the multilevel interconnect configuration in which the interconnect layers including the interconnect line 407 and the interlayer dielectric film 405 are stacked is formed as shown in FIG. 6C.

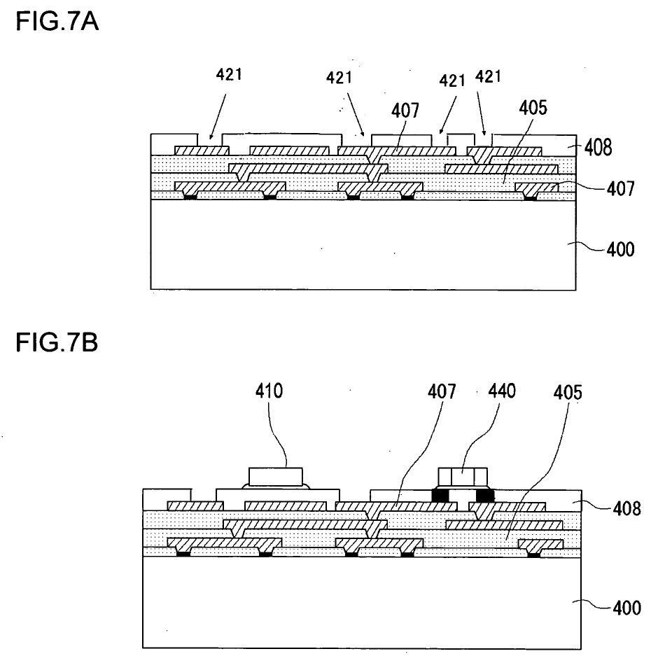

After the formation of the solder resist layer 408, the contact hole 421 is formed in the solder resist layer 408 by photo lithography using UV (i-line) and dry etching as shown in FIG. 7A. A dielectric film of epoxy resin is used as the material of the solder resist layer 408. Although dry etching is performed in the present embodiment, machining, chemical etching and laser processing may be also used.

As shown in FIG. 7B, the first element 410 and the circuit element 440 are mounted on the solder resist layer 408. The first element 410 may be, for example, semiconductor chips such as a transistor, a diode and an IC chip, or passive elements such as a chip capacitor and a chip resistor. Face-down semiconductor elements such as a CSP and a BGA can be also mounted. In the configuration shown in FIG. 7B, the first element 410 is a bare semiconductor chip (a transistor chip) and the circuit element 440 is a chip capacitor. These elements are stuck on the solder resist layer 408. Then plasma treatment is performed. The condition of the plasma exposure is arbitrarily determined corresponding to used resin material so that the surface property having excellent adhesiveness at the interface can be obtained. A bias voltage is preferably not applied to the substrate. For example, the following condition is adopted.
Bias voltage: no voltage applied.
Plasma gas: argon of 10 to 20 sccm and oxygen of 0 to 10 sccm.

By the plasma exposure, the etching residue on the surface of the interconnect line 407 is removed, the surface property of the solder resist layer 408 is modified, and a cluster of micro projections with an average diameter of 1 to 10 nm and a number density of about 1×10³ μm⁻² is formed on the surface. Simultaneously, the surface property of the first element 410 is changed into that having a strong adhesiveness for the adhesion layer 411.

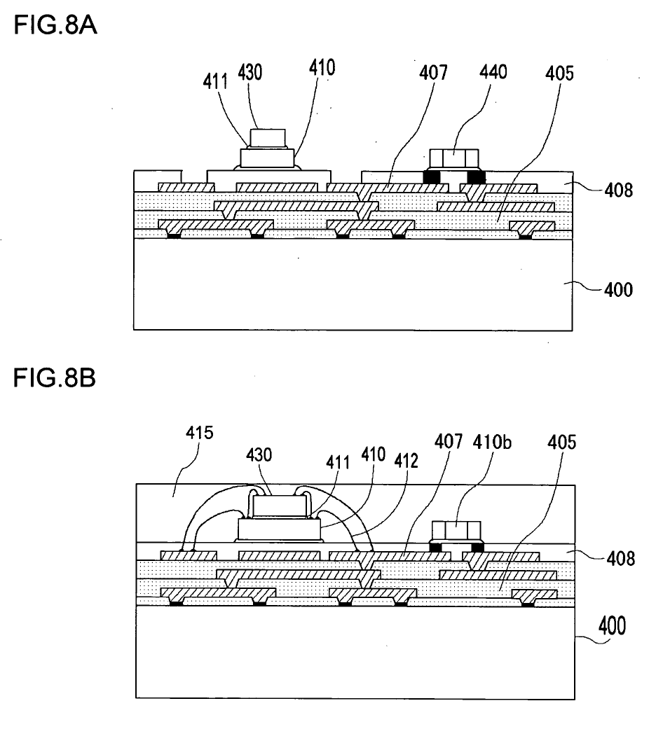

The second element 430 is mounted on the adhesion layer 411 formed on the first element 410 as shown in FIG. 8A. The adhesiveness between the first element 410 and the adhesion layer 411 is favorable by the modification of the surface property of the first element 410.

After connecting between the second element 430 and the first element 410, between the second element 430 and the interconnect line 407, and between the first element 410 and the interconnect line 407 by the gold wires 412, they are molded by the mold resin 415 as shown in FIG. 8B. FIG. 8B shows a molded configuration. The mold process of semiconductor elements is performed simultaneously for a plurality of modules mounted on the metal foil 400 by using a mold. Transfer mold, injection mold, potting and dipping can be used for the mold process. When a thermosetting resin such as an epoxy resin is used, the transfer mold or potting may be adopted. When a thermoplastic resin such as a polyimide resin and a polyphenylene sulfide is used, the injection mold can be adopted.

After removing the metal foil 400 from the configuration shown in FIG. 8B, solder balls are formed on the backside surface. The metal foil 400 can be removed by polishing, grinding, etching or laser vaporization, for example. The method adopted in the present embodiment is as follows: the metal foil 400 is overall grinded about 50 μm by a polisher or a grinder, and the rest of the metal foil 400 is removed by chemical wet etching. Wet etching may be used also for removing the entire metal foil 400. By these processes, the lower surface of the interconnect line 407 in the first layer is exposed on the opposite side of the surface where the semiconductor elements are mounted. With this configuration, a module having a flat underside surface is obtained in the present embodiment. Therefore, when the semiconductor device is mounted, it moves horizontally by surface tension of solder and so on, and an advantage in the processing, i.e., easy self alignment, can be obtained.

After that, the solder ball 420 is formed by sticking a conductive material such as solder on the backside surface of the conductive film 402, which is exposed by removing the metal foil 400. Then the semiconductor device shown in FIG. 4 is obtained by dicing. The wafer is subsequently cut by dicing so that a chip of the semiconductor device can be obtained. The metal foil 400 is a supporting substrate before removing the metal foil 400 as described above. The metal foil 400 is also used as an electrode in the electric field plating process to form the interconnect line 407. Furthermore, also when the mold resin 415 is molded, the metal foil 400 makes the workability of carrying to a mold and of mounting in the mold favorable.

In the semiconductor according to the present embodiment, the property of surface of the first element 410 is modified by Ar plasma treatment in the process shown in FIG. 7B so that the surface has an excellent adhesiveness for the adhesion layer 411. As a result, the interface adhesiveness between the first element 410 and the second element 430 formed thereon is significantly improved, and the yield rate and the element reliability are advanced. The property of surface of the solder resist layer 408 is simultaneously modified by the plasma treatment. As a result, the interface adhesiveness between the solder resist layer 408 and the mold resin 415 is significantly improved, inducing the advantage in reliability.

Second Embodiment

Although the first element 410 and the circuit element 440 are bonded on the solder resist layer 408 by solder in the first embodiment, the elements can be also bonded by adhesive etc., not solder. In this case, the configuration may have no solder resist layer.

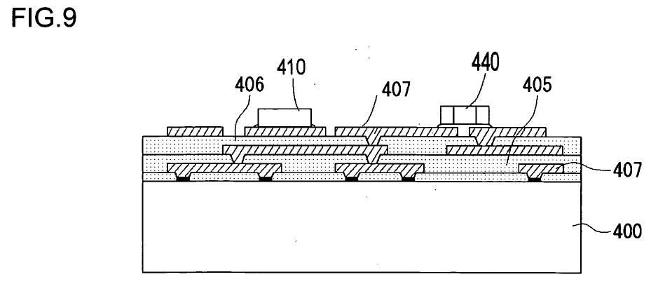

FIG. 9 shows a configuration in which elements are bonded on interconnect lines directly without solder resist layer. The multilevel interconnect configuration is similar to the configuration described in the first embodiment. An epoxy resin is used for the interlayer dielectric film 405 in the present embodiment.

The semiconductor device according to the present embodiment can be formed as follows. First, the processes shown in FIGS. 6A to 6C are implemented. After that, the first element 410 and the circuit element 440 are bonded on the surface by adhesive as shown in FIG. 9. The surface on which the elements are formed is then treated by plasma. The plasma treatment is performed under the condition similar to that in the first embodiment. The property of surface of the first element 410 is modified by the plasma exposure.

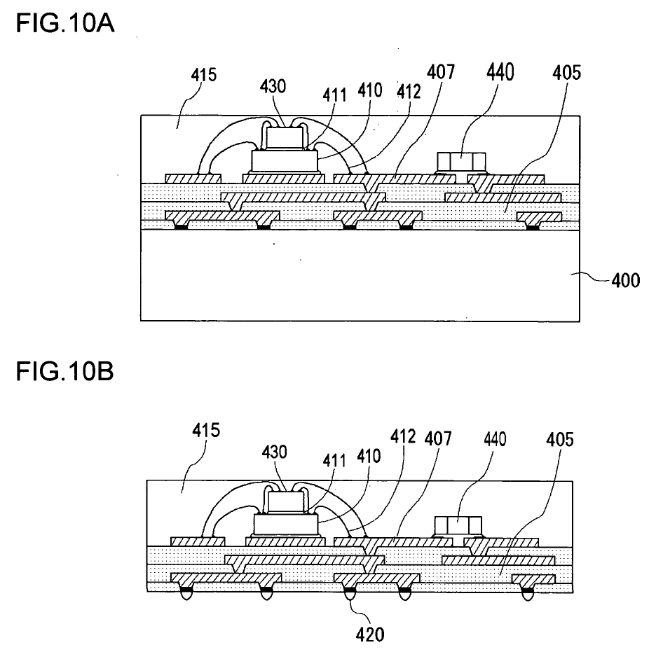

Next, the second element 430 is formed on the first element 410 as shown in FIG. 10A. In the present embodiment, the property of surface of the first element 410 is modified by Ar plasma. Therefore, an excellent adhesiveness of the interface between the first element 410 and the second element 430 can be obtained. As a result, the reliability of the semiconductor device can be significantly improved.

After connecting between the second element 430 and the first element 410, between the second element 430 and the interconnect line 407, and between the first element 410 and the interconnect line 407 by gold wires 412, all of them is molded by the mold resin 415. FIG. 10B shows a molded configuration. The mold process of semiconductor elements is performed simultaneously for a plurality of modules mounted on the metal foil 400 by using a mold. Transfer mold, injection mold, potting and dipping can be used for the mold process. When a thermosetting resin such as an epoxy resin is used, the transfer mold or potting can be adopted. When a thermoplastic resin such as a polyimide resin and a polyphenylene sulfide is used, the injection mold can be adopted.

Third Embodiment

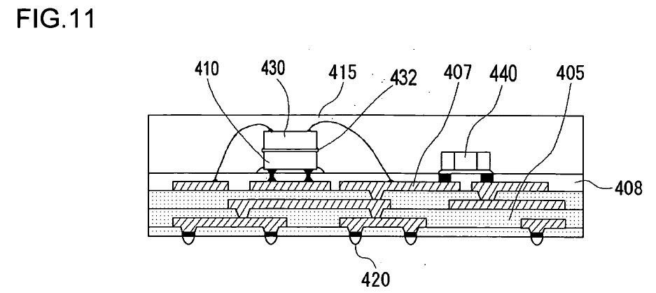

When the first element 410 is mounted, flip mounting in which the first element 410 is placed face down is adopted as shown in FIG. 11, although the wire bonding method is adopted in the first and the second embodiments. As shown in FIG. 11, the first element 410 is connected with the interconnect line 407 by solder, and the second element 430 is connected with the interconnect line 407 by wire bonding.

In the present embodiment, the back side of a silicon substrate constitutes the upper surface of the first element 410. This surface becomes a plasma treatment surface. For example, the following condition is adopted.
Bias voltage: no voltage applied
Plasma gas: argon of 10 to 20 sccm and oxygen of 0 to 10 sccm.

By the plasma treatment, the back side surface of the silicon substrate is cleaned up by removing organic materials attached thereon, and the surface property is changed into that having excellent adhesiveness. As a result, the adhesiveness for the second element 43 formed thereon is improved.

### EXAMPLE

The argon plasma treatment for a polyimide film on a semiconductor chip is performed under the following condition:
Bias voltage: no voltage applied
Plasma gas: argon of 10 sccm and oxygen of 0 sccm
RF power: 500 W
Pressure: 20 Pa
Treatment time: 20 sec.

The process described in the first embodiment was implemented under the aforementioned condition, and a semiconductor device was formed. The evaluation of this semiconductor shows a favorable heat-cycle resistance, and a good result is also obtained in a pressure cooker test.

Although the present invention has been described by way of exemplary embodiments, it should be understood that many changes and substitutions may be made by those skilled in the art without departing from the spirit and the scope of the present invention which is defined only by the appended claims.

1. A semiconductor device comprising:
a first semiconductor chip; and
a second semiconductor chip mounted on the first semiconductor chip, wherein an upper surface of the first semiconductor chip is a plasma treatment surface, and the second semiconductor chip is mounted on the plasma treatment surface.

2. The semiconductor device of claim 1, wherein the plasma treatment surface comprises a surface of the first semiconductor chip.

3. The semiconductor device of claim 1, wherein the plasma treatment surface comprises a surface of an adhesion layer formed on the first semiconductor chip.

4. The semiconductor device of claim 1, wherein the plasma treatment surface comprises a back side surface of a semiconductor substrate on the first semiconductor chip.

5. The semiconductor device of claim 1, wherein the first semiconductor chip is mounted on an upper surface of a dielectric film, and the plasma treatment surface comprises the upper surface of the dielectric film.

6. The semiconductor device of claim 5, wherein the dielectric film is comprised of a melamine derivative.

7. The semiconductor device of claim 5, wherein the upper surface of the dielectric film has a cluster of micro projections.

8. The semiconductor device of claim 1, wherein the first semiconductor chip is mounted on an upper surface of a metal interconnect line, and the plasma treatment surface comprises the upper surface of the metal interconnect line.

9. The semiconductor device of claim 1, further comprising a base material provided with a conductor circuit, wherein at least a part of the conductor circuit is exposed on a underside surface of the base material, wherein the first semiconductor chip and the second semiconductor chip are formed on an upper side of the base material.

10. A manufacturing method of a semiconductor device comprising:
forming a first semiconductor chip on a base material;
performing plasma treatment for a surface of the base material and an upper surface of the first semiconductor chip; and
forming a second semiconductor chip on the upper surface of the first semiconductor chip, which is treated by the plasma.

11. The manufacturing method of a semiconductor device of claim 10, wherein the plasma treatment is implemented by using a plasma gas comprising an inert gas and with no bias voltage applied to the base material.

12. The manufacturing method of a semiconductor device of claim 10, wherein the plasma treatment is implemented to a surface comprising a surface of the first semiconductor chip.

13. The manufacturing method of a semiconductor device of claim 10 further comprising forming an adhesion layer on an upper surface of the first semiconductor chip before the plasma treatment, wherein the plasma treatment is implemented to a surface comprising a surface of the adhesion layer.

14. The manufacturing method of a semiconductor device of claim 10, wherein the first semiconductor chip, which is mounted on a semiconductor substrate, is formed on the base material so that the semiconductor substrate is located in an upper side, and the plasma treatment is implemented for an backside surface of the semiconductor substrate.

15. The manufacturing method of a semiconductor device of claim 10, wherein the surface of the base material comprises an upper surface of a dielectric film.

16. The manufacturing method of a semiconductor device of claim 15, wherein the dielectric film is comprised of a melamine derivative.

17. The manufacturing method of a semiconductor device of claim 15, wherein a cluster of micro projections are formed on the upper surface of the dielectric film by the plasma treatment.

18. The manufacturing method of a semiconductor device of claim 10, wherein the surface of the base material comprises an upper surface of a metal interconnect line.
